(19) United States
(12) Patent Application Publication
(10) Pub. No.: US 2016/0365353 A1
(43) Pub. Date: Dec. 15, 2016

(54) MANUFACTURING METHOD OF SEMICONDUCTOR DEVICE

(71) Applicant: KABUSHIKI KAISHA TOSHIBA, Tokyo (JP)

(72) Inventor: Tomonori AOYAMA, Yokkaichi (JP)

(73) Assignee: KABUSHIKI KAISHA TOSHIBA, Tokyo (JP)

(21) Appl. No.: 15/008,067

(22) Filed: Jan. 27, 2016

(30) Foreign Application Priority Data
Jun. 10, 2015 (JP) 2015-117526

(51) Int. Cl. H01L 27/115

(52) U.S. Cl. CPC H01L 27/11582

(57) ABSTRACT

In accordance with an embodiment, a manufacturing method of a semiconductor device includes forming a first film on an inner wall of a hole in a stack on a substrate, forming a polycrystalline silicon film on the first film, and conducting a thermal annealing treatment in an atmosphere of ozone or oxygen radical to reduce defects in an interface between the first film and the polycrystalline silicon film. In the stack second films and third films are repeatedly stacked on the substrate in this order more than once.

### CROSS REFERENCE TO RELATED APPLICATIONS

This application is based upon and claims the benefit of priority from the prior Japanese Patent Application No. 2015-117526, filed on Jun. 10, 2015, the entire contents of which are incorporated herein by reference.

### FIELD

Embodiments described herein relate generally to a manufacturing method of a semiconductor device.

### BACKGROUND

Recently, there has been known a semiconductor device having a structure in which metal-oxide-nitride-oxide-silicon (MONOS) structures are repeatedly stacked such as a three dimensional stacked structure flash memory (BiCS FLASH™) as a three-dimensional memory to achieve higher integration of a semiconductor memory.

In a semiconductor having such a structure, wiring lines for word lines and insulating films are stacked, a hole for a memory is then made, a block insulating film, a charge storage film, and a tunnel insulating film are deposited on the inner side of the hole, and then an amorphous silicon film to be a channel is deposited.

A silicon oxide film is mostly used as the tunnel insulating film, however, a defect may be caused by, for example, oxygen deficiency during the deposition of amorphous silicon. This leads to problems such as the increase of interface state density and a fixed charge and the deterioration in the reliability of the insulating films.

Amorphous silicon is crystallized into polycrystalline silicon in order to improve the mobility of silicon for the channel. However, if the grain diameter of polycrystalline silicon is small, there are grown more grain boundaries, and the mobility is lower. This leads to another problem of being unable to ensure a sufficient cell current of a memory cell.

### BRIEF DESCRIPTION OF THE DRAWINGS

FIG. 1 to FIG. 3 are examples of schematic sectional views illustrating a manufacturing method of a semiconductor device according to Embodiment 1;

FIG. 4 is an example of a partially enlarged view of FIG. 3;

FIG. 5 is an example of a schematic sectional view illustrating the manufacturing method of the semiconductor device according to Embodiment 1;

FIG. 6 is an example of a partially enlarged view of FIG. 5;

FIG. 7 is an example of a schematic sectional view illustrating the manufacturing method of the semiconductor device according to Embodiment 1;

FIG. 8 is an example of a partially enlarged view of FIG. 7;

FIG. 9 is an example of a schematic sectional view illustrating the manufacturing method of the semiconductor device according to Embodiment 1; and

FIG. 10 is a diagram showing an example of a profile of temperature versus time in first to third annealings.

### DETAILED DESCRIPTION

In accordance with an embodiment, a manufacturing method of a semiconductor device includes Forming a first insulating film on an inner wall of a hole in a stack on a substrate, forming a polycrystalline silicon film on the first insulating film, and conducting a thermal annealing treatment in an atmosphere of ozone or oxygen radical to reduce defects in an interface between the first insulating film and the polycrystalline silicon film. In the stack second insulating films and third films are repeatedly stacked on the substrate in this order more than once.

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus.

In the specification of the present application, “stacking” not only includes stacking layers in contact with each other but also includes staking layers with another layer interposed in between. “Providing on” not only includes providing a layer in direct contact with a layer but also includes providing a layer on a layer with another layer interposed therebetween. Moreover, terms indicating directions such as “upper” and “lower” in the explanation show relative directions when a wiring formation side in a given layer on a later-described substrate is set as the top. Therefore, the directions may be different from actual directions based on gravitational acceleration directions.

### (1) Embodiment 1

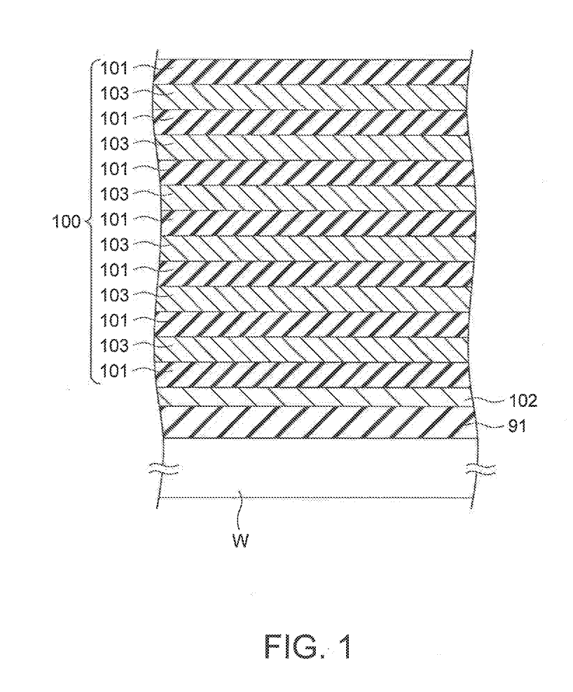

A manufacturing method of a semiconductor device according to Embodiment 1 will be described with reference to FIG. 1 to FIG. 10.

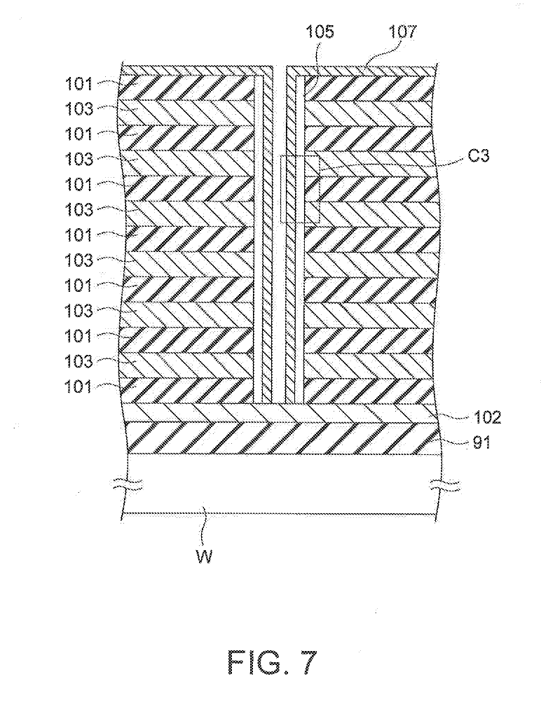

First, as shown in FIG. 1, a silicon oxide film (SiO₂) 91 is formed on a silicon wafer W, and a silicon (Si) film 102 is then formed on the silicon oxide film (SiO₂) 91. The silicon oxide film (SiO₂) 91 is an insulating film for isolating the silicon (Si) film 102 from the silicon wafer W. The silicon (Si) film 102 is formed by being doped with an impurity such as boron, and is finally connected to a silicon channel (see the sign 107 in FIG. 7) and thus servers as a wiring line. In the present embodiment, the silicon wafer W corresponds to, for example, a substrate. It is possible to use, as the substrate, not only the silicon wafer but also, for example, a glass substrate, a ceramic substrate, or a nitride semiconductor substrate.

Silicon oxide (SiO₂) films 101 and polycrystalline silicon (Poly-Si) films 103 are then alternately formed on the silicon (Si) film 102 in this order more than once to form a stack 100. In the formation of the polycrystalline silicon (Poly-Si) films 103, an impurity such as phosphorus or boron is used for doping. In the present embodiment, the silicon oxide (SiO₂) film 101 corresponds to, for example, a second film, and the polycrystalline silicon (Poly-Si) film 103 corresponds to, for example, a third film. It is to be noted that a refractory metal film may be used as substitute for the polycrystalline silicon (Poly-Si) film 103 constituting the stack 100. For example, tungsten could be used as the refractory metal.

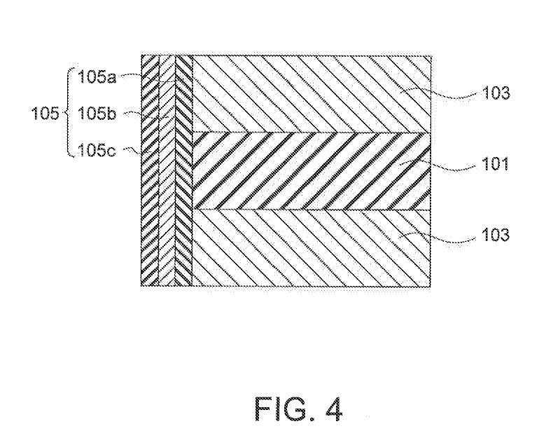

Although not shown in particular, transistors for operating peripheral circuits are formed in a peripheral region of the stack 100 on the silicon wafer W. The polycrystalline silicon (Poly-Si) film 103 interposed between the silicon oxide (SiO₂) films 101 not only serves as a gate to apply a voltage to each of cell insulating films (see the sign 105a in FIG. 4) as a word line but can also be used as a gate electrode of a selected gate.

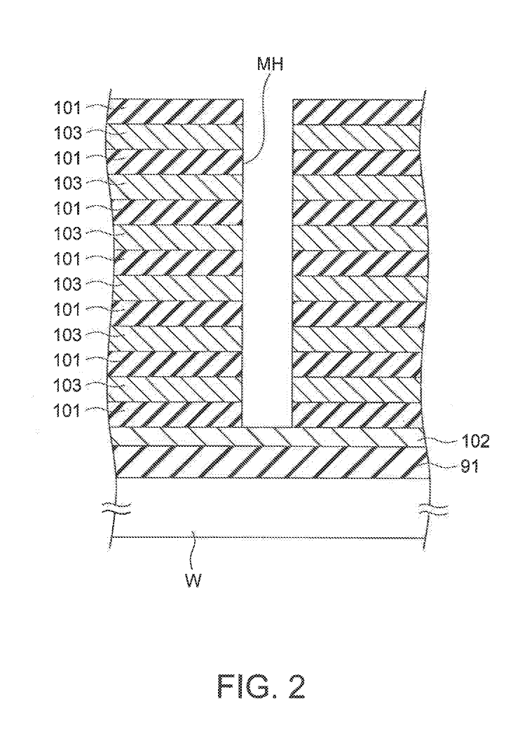

Further, after a mask material is deposited, a memory hole MH is made by patterning that uses a lithographic method and a reactive ion etching method until the wiring line 102 is exposed as shown in FIG. 2, and the mask material is removed later.

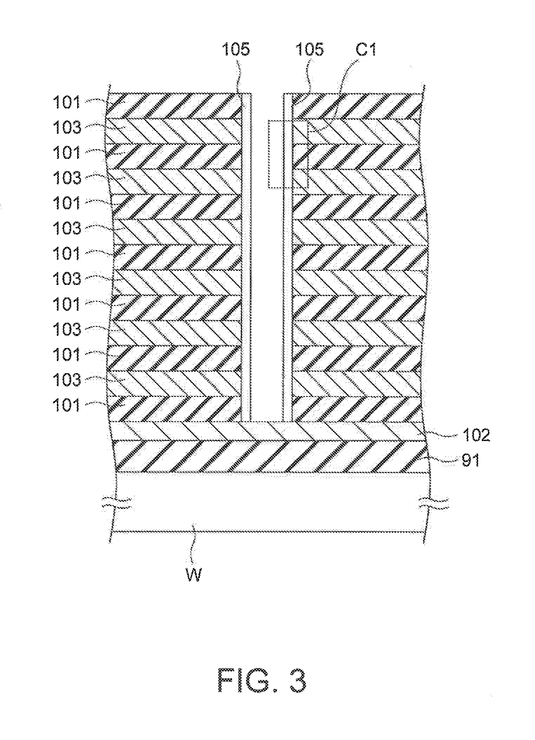

As shown in FIG. 3, a memory insulating film 105 is then formed on the inner wall of the memory hole MM.

An enlarged view of a region C1 in FIG. 3 is shown in FIG. 4. The memory insulating film 105 includes a block insulating film 105a formed on the inner wall of the memory hole MM, a charge storage film 105b formed on the block insulating film 105a, and a tunnel insulating film 105c formed on the charge storage film 105b.

The block insulating film 105a is made of, for example, a silicon oxide (SiO₂) film or an aluminum oxide (Al₂O₃) film. The charge storage film 105b is made of, for example, a silicon nitride (SiN) film. The tunnel insulating film 105c is made of, for example, a silicon oxide (SiO₂) film. In the present embodiment, the tunnel insulating film 105c corresponds to, for example, a first film, and the charge storage film 105b corresponds to, for example, a fourth film.

A manufacturing method of the memory insulating film 105 in FIG. 3 is specifically described. First, the block insulating film 105a, the charge storage film 105b, and the tunnel insulating film 105c are sequentially formed on the entire surface in this order. Then the block insulating film 105a, the charge storage film 105b, and the tunnel insulating film are selectively removed by using, for example, the reactive ion etching. It is only necessary to leave the block insulating film 105a, the charge storage film 105b, and the tunnel insulating film 105c exclusively on the sidewall of the memory hole MH. In this instance, the following method may be used: the surface of the memory insulating film 105 is covered with, for example, a thin film of, for example, silicon, and the covering thin film of, for example, silicon is removed after the wiring line 102 on the bottom of the memory hole MH is exposed by the reactive ion etching method.

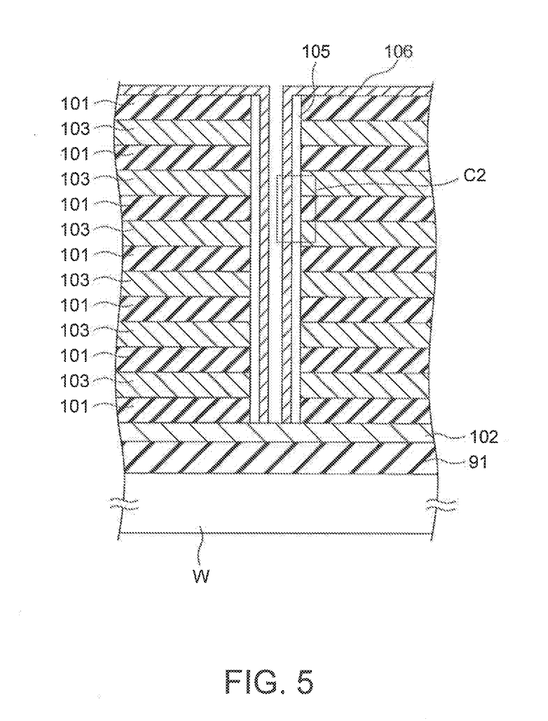

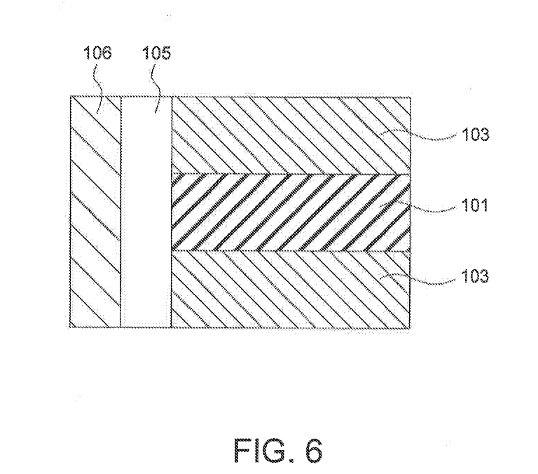

As shown in FIG. 5, an amorphous silicon (a-Si) film 106 having a thickness of about 10 nm is then formed on the entire surface. An enlarged view of a region C2 in FIG. 5 is shown in FIG. 6.

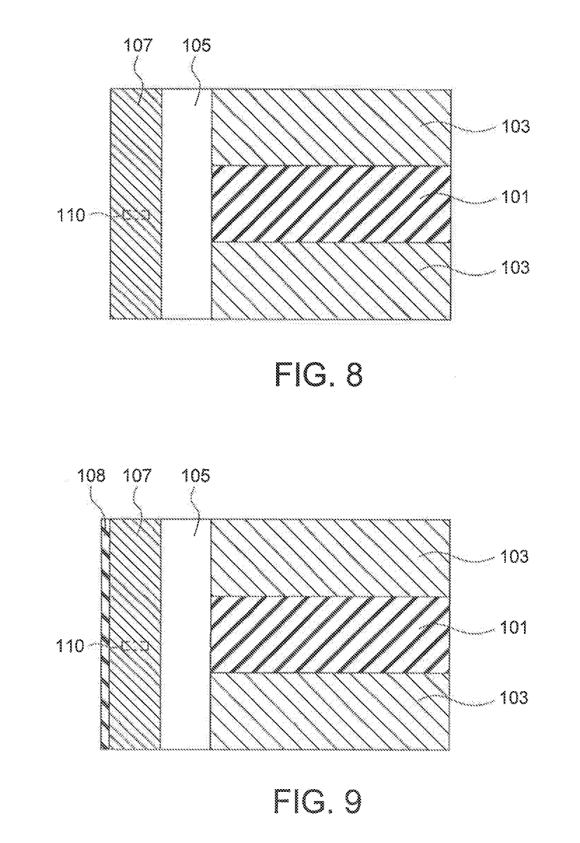

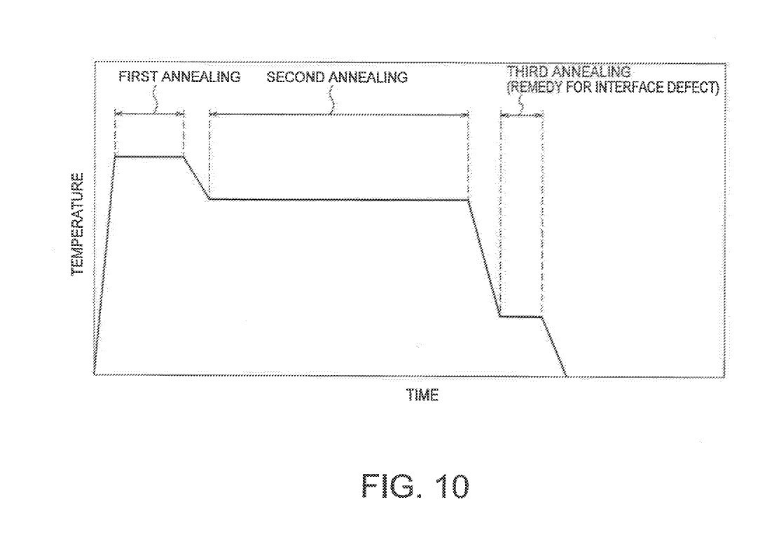

A heat treatment is then conducted for about 1 hour in nitrogen (N₂) gas atmosphere at about 590° C. as first annealing (see FIG. 10). As a result, an initial nucleus of silicon (Si) is formed. The temperature is then dropped to about 570° C., and a heat treatment is conducted for about 4 hours in a nitrogen (N₂) gas atmosphere as second annealing (see FIG. 10). Thus, as shown in FIG. 7, the whole amorphous silicon (a-Si) film 106 becomes a polycrystalline silicon (Poly-Si) film 107. Here, the first annealing is followed by the second annealing at a temperature of about 570° C. without the exposure of the amorphous silicon (a-Si) film 106 to an open air atmosphere or without the drop of the temperature to the room temperature. Consequently, crystal growth takes place from the initial nucleus by the second annealing without the formation of any stacking fault in the amorphous silicon (a-Si) film 106, and the grown crystal entirely becomes the polycrystalline silicon (Poly-Si) film 107 as shown in FIG. 8 which is an enlarged view of a region C3 in FIG. 7, and finally constitutes a silicon channel. An example of crystal formed by the second annealing is schematically shown by the sign 110 in FIG. 8. The grain diameter of the crystal 110 measures about 100 nm to about 200 nm.

Further, the temperature is dropped to about 300° C., and a heat treatment is conducted for about 15 minutes in an ozone gas as third annealing (see FIG. 10). Thus, as shown in FIG. 9, a silicon oxide (SiO₂) film 108 is formed on the surface of the polycrystalline silicon (Poly-Si) film 107. The defect in the interface between the silicon channel and the tunnel insulating film is remedied by this third annealing. An evaluation of interface state density using a capacitor shows that the interface state density decreases from 5×10¹⁰ cm⁻² eV⁻¹ to 3×10⁹ cm⁻² eV⁻¹. In the present embodiment, the third annealing is conducted in the ozone atmosphere, so that the defect in the interface can be remedied even by the low-temperature and short-time treatment for about 15 minutes at about 300° C.

Furthermore, it is found out that the silicon oxide (SiO₂) film 108 formed on the surface of the polycrystalline silicon (Poly-Si) film 107 by the third annealing has a small thickness of 2 nm or less. Therefore, if the inside diameter of a cavity in the memory hole after the formation of the polycrystalline silicon (Poly-Si) film 107 is at least 5 nm or more, the memory hole MH is not blocked by the silicon oxide film 108 at the top of the memory hole NIH.

The defect can be remedied by the third annealing at 250° C. or more. However, at more than 600° C., ozone is deactivated, and its effects are reduced. It is therefore preferable that the temperature range of the third annealing is between 250° C. or more and 600° C. or less. When oxygen radical is used instead of ozone, the temperature range is preferably between 250° C. or more and 800° C. or less.

In the present embodiment, the initial nucleation, the crystal growth, and the remedy for the interface are conducted by the use of the same electric furnace. A profile of temperature versus time is shown in FIG. 10.

The first annealing and the second annealing are conducted in the nitrogen (N₂) atmosphere in the present embodiment, but may be conducted in an inert gas atmosphere of, for example, argon (Ar).

The third annealing is conducted in the ozone (O₃) atmosphere in the present embodiment, but may be conducted in the oxygen radical atmosphere.

Although the temperature and time of the first annealing are about 590° C. and about 1 hour in the embodiment described above, the temperature of the first annealing may be more than 590° C. However, the density of the initial nucleus is determined by the temperature and time of the first annealing. Therefore, the crystalline grain diameter substantially equal to the above-mentioned grain diameter is obtained by the second annealing for 4 hours at 570° C. if the treatment time is adjusted so that the treatment time may be 20 minutes at a temperature of 650° C. or the treatment time may be 5 minutes at a temperature of 690° C.

However, if the temperature of the first annealing is set at 700° C. or more, it is difficult to control the initial nucleus density. Thus, it is preferable to conduct the first annealing at a temperature of less than 700° C. The initial nucleation temperature may be lower than the above-mentioned temperature, however, a heat treatment of about 3 hours is then required to obtain the crystalline grain diameter substantially equal to the above-mentioned grain diameter, for example, when the first annealing temperature is 580° C. Therefore, the temperature of the first annealing is preferably 590° C. or more if the productivity of a memory device is taken into consideration.

The temperature and time of the second annealing are not limited to the example described above and can also be changed. However, the higher the temperature of the second annealing is, the more likely nuclei are to be additionally formed in amorphous silicon. Therefore, the upper limit of the temperature is preferably 590° C. In contrast, it is also possible to reduce the formation density of new nuclei by decreasing the temperature of the second annealing compared to the above-mentioned temperature. However, long-time annealing is then required to obtain a large crystalline grain diameter, which deteriorates the productivity. Therefore, the temperature of the second annealing is preferably 560° C. or more.

For the time of the second annealing, it is necessary to take into consideration the density of the initial nucleus formed in the first annealing. More specifically, the required time is equal to or more than the time in which a (111) face of silicon grows up to a distance which is half the space between an initial nucleus and an initial nucleus. For example, when the space between the initial nucleus and the initial nucleus is 300 nm, it requires a time in which the (111) face of silicon grows to 150 nm or more in length. For example, when the temperature of the second annealing is 570° C., amorphous silicon does not remain if the annealing is conducted for 5 hours or more.

According to the manufacturing method of the semiconductor device in the present embodiment, the third annealing that uses ozone or oxygen radical is conducted at a temperature lower than the temperature of the second annealing for crystal growth. Therefore, the defect in the interface between the silicon channel and the tunnel insulating film can be remedied to reduce the interface state density and the fixed charge, and the blockage of the top of the memory hole can be prevented.

### (2) Embodiment 2

A manufacturing method of a semiconductor device according to Embodiment 2 will be described.

The processes in the present embodiment are the same as those in Embodiment 1 described above from the process of forming the stack 100 on the silicon wafer W (see FIG. 1) to the process of changing the amorphous silicon 106 into the polycrystalline silicon 107 by the second annealing treatment (see FIG. 8).

In the present embodiment, the silicon wafer W is once taken out of the unshown electric furnace after the second annealing treatment is conducted, and is then subjected to microwave annealing for about ten minutes at about 300° C. in the oxygen atmosphere. Microwaves shake a dangling bond of silicon in a defective part of the interface between the silicon channel 107 and the tunnel insulating film 105c, so that the defective part can be efficiently remedied without the use of ozone or oxygen radical. In this case, the thickness of the silicon oxide film 108 formed on the surface of the polycrystalline silicon film 107 can be about 1 nm.

Although the thickness of the polycrystalline silicon film 107 to be the channel is about 10 nm in the present embodiment, the polycrystalline silicon film 107 having a large thickness of 20 nm or 30 nm or having a small thickness of 7 nm or 5 nm is also practicable.

According to the manufacturing method of the semiconductor device in the present embodiment, it is possible to remedy the defect in the whole memory insulating film to reduce the interface state density and the fixed charge, and also prevent the blockage of the top of the memory hole by conducting low-temperature microwave annealing using oxygen.

According to the manufacturing method of the semiconductor device in at least one embodiment described above, crystal grows without the drop of the temperature to the room temperature after the formation of the initial nucleus when the amorphous silicon to be the channel is crystallized. Therefore, it is possible to prevent the formation of a stacking fault which may be formed on the surface of the initial nucleus, form a silicon channel having a large grain diameter, and improve channel mobility. Consequently, it is possible to improve a cell current and improve long-term reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A manufacturing method of a semiconductor device comprising:
forming a first film on an inner wall of a hole in a stack in which second films and third films are repeatedly stacked on a substrate in this order more than once;
forming a polycrystalline silicon film on the first film;
conducting a thermal annealing treatment in an atmosphere of ozone or oxygen radical to reduce defects in an interface between the first film and the polycrystalline silicon film.

2. The method of claim 1,
wherein the thermal annealing treatment is conducted at a temperature of 250° C. or more and 800° C. or less.

3. The method of claim 1,
wherein the polycrystalline silicon film is formed after the formation of an amorphous silicon film on the first film by subjecting the amorphous silicon film to a thermal annealing treatment at a temperature higher than the temperature of the former thermal annealing treatment before the former thermal annealing treatment is conducted.

4. The method of claim 3,
wherein the stack is subjected to the thermal annealing treatment to form the polycrystalline silicon film without exposure to an open air atmosphere and without temperature decrease to the room temperature after the amorphous silicon film is formed.

5. The method of claim 1, further comprising forming a fourth film between the inner wall of the hole and the first film,
wherein the semiconductor device comprises a memory in the hole,
the polycrystalline silicon film corresponds to a channel of the memory,
the first film corresponds to a tunnel insulating film of the memory, and
the fourth films corresponds to a charge storage film of the memory.

6. A manufacturing method of a semiconductor device comprising:
forming a first film on the inner wall of a hole provided in a stack in which second films and third films are repeatedly stacked on a substrate in this order more than once;
forming an amorphous silicon film on the first film;
subjecting the amorphous silicon film to a thermal annealing treatment to form a polycrystalline silicon film; and
subjecting the polycrystalline silicon film to a thermal annealing treatment in an atmosphere of ozone or oxygen radical at a temperature less than or equal to the temperature of the former thermal annealing treatment after the former thermal annealing treatment.

7. The method of claim 6,
wherein the stack is subjected to the thermal annealing treatment to form the polycrystalline silicon film without exposure to an open air atmosphere and without temperature decrease to the room temperature after the amorphous silicon film is formed.

8. The method of claim 6, further comprising forming a fourth film between the inner wall of the hole and the first film,
wherein the semiconductor device comprises a memory in the hole,
the polycrystalline silicon film corresponds to a channel of the memory,
the first film corresponds to a tunnel insulating film of the memory, and
the fourth film corresponds to a charge storage film of the memory.

9. A manufacturing method of a semiconductor device comprising:
forming a first film and a polycrystalline silicon film on the first film on the inner wall of a hole provided in a stack in which second films and third films are repeatedly stacked on a substrate in this order more than once; and
subjecting the polycrystalline silicon film to a microwave annealing treatment in an oxygen atmosphere.

10. The method of claim 9, further comprising forming a fourth film between the inner wall of the hole and the first film,
wherein the semiconductor device comprises a memory in the hole,
the polycrystalline silicon film corresponds to a channel of the memory,
the first film corresponds to a tunnel insulating film of the memory, and
the fourth film corresponds to a charge storage film of the memory.
